(19) United States
(12) Patent Application Publication
(10) Pub. No.: US 2011/0042812 A1
(43) Pub. Date: Feb. 24, 2011

(54) Electronic device and method of manufacturing the same

(75) Inventors: Kimiharu Kayukawa, Nagoya-city (JP); Rikiya Kamimura, Toyoake-city (JP); Masaya Mizutani, Anjo-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/805,396

(22) Filed: Jul. 29, 2010

(30) Foreign Application Priority Data
Aug. 19, 2009 (JP) 2009-189783

(51) Int. Cl. H01L 23/48; H01L 21/50

(52) U.S. Cl. 257/741; 438/107; 257/E23.01; 257/E21.499

(57) ABSTRACT

An electronic device includes a power element on a first substrate and an electronic component on a second substrate. The first and second substrates are stacked so that the power element and the electronic component can be located between the first and second substrates. A first end of a first wire is connected to the power element. A second end of the first wire is connected to the first substrate. A middle portion of the first wire projects toward the second substrate. A first end of a second wire is connected to the power element. A second end of the wire extends above a top of the middle portion of the first conductive member and is connected to the second substrate.

### CROSS REFERENCE TO RELATED APPLICATION

This application is based on and incorporates herein by reference Japanese Patent Application No. 2009-189783 filed on Aug. 19, 2009.

### FIELD OF THE INVENTION

The present invention relates to an electronic device including first and second substrates that are stacked together, a power element mounted on a surface of the first substrate, and an electronic component mounted on a surface of the second substrate facing the surface of the first substrate. The present invention also relates to a method of manufacturing the electronic device.

### BACKGROUND OF THE INVENTION

JP-A-2001-85613 discloses an electronic device formed with first and second substrates. The first and second substrates are stacked together so that surfaces of the first and second substrates can face each other. A power element is mounted on the surface of the first substrate and electrically connected to the first substrate through a wire or the like.

In the electronic device disclosed in JP-A-2001-85613, the first and second substrates are electrically connected together through a lead, and the power element and the second substrate are connected together through the lead. Since the lead is located at an end of the second substrate, it is difficult to reduce a planar size of the electronic device.

JP-4062191 discloses another electronic device formed with first and second substrates. The first and second substrates are stacked together so that surfaces of the first and second substrates can face each other. A semiconductor element is mounted on the surface of the first substrate. The second substrate is a wiring layer. The semiconductor element is electrically connected to the second substrate through solder or the like.

FIG. 1 of JP-4062191 shows that the semiconductor element is connected to the first substrate through a bonding wire. The bonding wire has a loop shape and projects over the semiconductor element. The first and second substrates are displaced from each other in a planer direction to prevent the second substrate from interfering with the bonding wire. Therefore, it is difficult to reduce a planar size of the electronic device.

FIG. 5 of JP-4062191 shows that the semiconductor element is connected to the first substrate through the bonding wire without displacing the first and second substrates from each other in the planar direction. However, the semiconductor element is connected to the second substrate through the first substrate without being directly connected to the second substrate.

For forgoing reasons, it is difficult to reduce a planer size of the electronic device disclosed in JP-4062191.

Further, in the structure shown in FIG. 1 of JP-4062191, since the semiconductor element is soldered to the second substrate, there is almost no space between the first and second substrates. Therefore, it is difficult to mount an electronic component on the facing surface of the second substrate. In the structure shown in FIG. 5 of JP-4062191, there may be space for mounting an electronic component on the facing surface of the second substrate. However, since the semiconductor element is not directly connected to the second substrate, it is difficult to reduce the size of the electronic device.

### SUMMARY OF THE INVENTION

In view of the above, it is an object of the present invention to provide an electronic device having a reduced size and including first and second substrates that are stacked together, a power element mounted on a surface of the first substrate, and an electronic component mounted on a surface of the second substrate facing the surface of the first substrate. It is another object of the present invention to provide a method of manufacturing the electronic device.

According to an aspect of the present invention, an electronic device includes a first substrate, a second substrate, a power element, an electronic component, a first conductive member, and a second conductive member. The first substrate has a surface. A surface of the first substrate faces a surface of the second substrate. The power element is mounted on the surface of the first substrate and has a surface facing the surface of the second substrate. The electronic component is mounted on the surface of the second substrate. The first conductive member electrically connects the power element to the first substrate. The first conductive member has a first end connected to the surface of the power element, a second end connected to the surface of the first substrate, and a middle portion between the first and second. The middle portion of the first conductive member projects toward the second substrate so that a top of the middle portion is located closer to the surface of the second substrate than the surface of the power element. The second conductive member electrically connects the power element to the second substrate. The second conductive member has a first end connected to the surface of the power element and a second end extending above the top of the middle portion of the first conductive member and connected to the surface of the second substrate. The surfaces of the first and second substrates are spaced from each other by a predetermined distance that prevents the power element from being in contact with the surface of the second substrate, prevents the electronic component from being in contact with the surface of the first substrate, and prevents the first conductive member from being in contact with the surface of the second substrate.

According to another aspect of the present invention, a method of manufacturing an electronic device includes placing a back surface of a power element on a surface of a first substrate, placing an electronic component on a surface of a second substrate, and connecting a first conductive member to each of the power element and the first substrate in such a manner that a first end of the first conductive member is connected to a front surface of the power element, a second end of the first conductive member is connected to the surface of the first substrate, and a middle portion between the first and second ends of the first conductive member projects in a direction away from the surface of the first substrate. The method further includes preparing a jig having a pair of facing surfaces that are engageable with each other, preparing a second conductive member having a longitudinal direction, and holding a middle portion of the second conductive member in the longitudinal direction between the pair of facing surfaces of the jig so that the middle portion of the second conductive member is bent in a direction crossing the longitudinal direction. The method further includes connecting a first end of the second conductive member to the front surface of the power element while keeping the middle portion of the second conductive member held between the pair of facing surfaces of the jig in such a manner that the longitudinal direction of the second conductive member is perpendicular to the front surface of the power element and that a second end of the first conductive member is located above a tip of the middle portion of the first conductive member. The method further includes positioning the first and second substrates with respect to each other in such a manner the surfaces of the first and second substrates face each other with a predetermined distance that prevents the power element from being in contact with the surface of the second substrate, prevents the electronic component from being in contact with the surface of the first substrate, and prevents the first conductive member from being in contact with the surface of the second substrate. The positioning step includes connecting the second end of the second conductive member to the surface of the second substrate.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram illustrating a cross-sectional view of an electronic device according to a first embodiment of the present invention;

FIGS. 2A-2C are diagrams illustrating a method of manufacturing the electronic device of FIG. 1;

FIG. 3 is a diagram illustrating a partial view of an electronic device according to a second embodiment of the present invention;

FIG. 4 is a diagram illustrating a partial view of an electronic device according to a third embodiment of the present invention;

FIG. 5 is a diagram illustrating a partial view of an electronic device according to a fourth embodiment of the present invention;

FIGS. 6A-6E are diagrams illustrating a second conductive member of an electronic device according to a fifth embodiment of the present invention;

FIG. 7 is a diagram illustrating a machine used in a method of manufacturing an electronic device according to a sixth embodiment of the present invention;

FIGS. 8A-8F are diagrams illustrating a process of forming a second conductive member of the electronic device according to the sixth embodiment;

FIGS. 9A-9C are diagrams illustrating a process of connecting the second conductive member to a power element of the electronic device according to the sixth embodiment; and

FIGS. 10A and 10B are diagrams illustrating a method of manufacturing an electronic device according to a seventh embodiment of the present invention.

### DETAILED DESCRIPTION OF THE PREFERRED EMBODIMENTS

Embodiments of the present invention are described below with reference to the drawings.

### First Embodiment

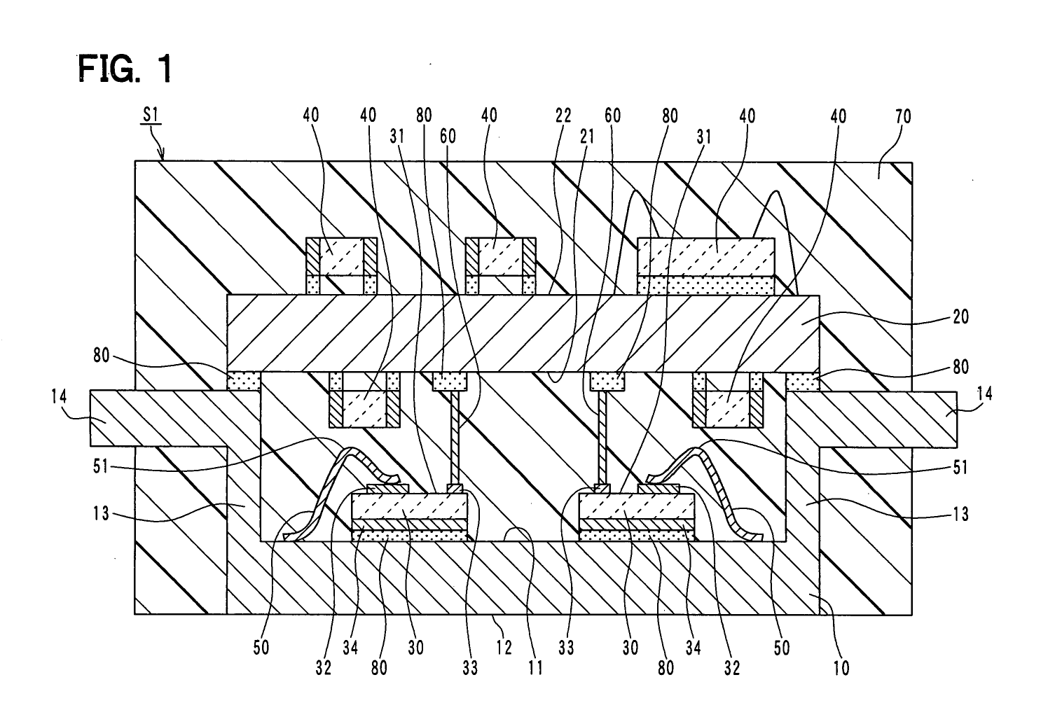

An electronic device S1 according to a first embodiment of the present invention is described below with reference to FIG. 1. The electronic device S1 includes a first substrate 10, a second substrate 20, a power element 30, an electronic component 40, a first conductive member 50, a second conductive member 60, and a molding resin 70. The first substrate 10 has a first surface 11 and a second surface 12 opposite to the first surface 11. The second substrate 20 has a first surface 21 and a second surface 22 opposite to the first surface 21. The first and second substrates 10, 20 are stacked so that the first surface 11 of the first substrate 10 can face the first surface 21 of the second substrate 20. The power element 30 is mounted on the first surface 11 of the first substrate 10. The electronic component 40 is mounted on the first surface 21 of the second substrate 20. The first conductive member 50 electrically connects the power element 30 to the first substrate 10. The second conductive member 60 electrically connects the power element 30 to the second substrate 20. The first substrate 10, the second substrate 20, the power element 30, the electronic component 40, the first conductive member 50, and the second conductive member 60 are encapsulated with the molding resin 70.

Examples of the first and second substrates 10, 20 can include various types of wiring boards, circuit boards, and lead frames, on which the power element 30 and the electronic component 40 can be mounted.

According to the first embodiment, the first substrate 10 is a lead frame made from a metal plate of copper (Cu), aluminum (Al), iron (Fe), or the like, and the second substrate 20 is a circuit board made from a printed board, a ceramic board, a flexible board, or the like.

The first substrate 10 is formed by patterning a metal plate into a shape having an island portion and a lead potion, for example, by pressing process or etching process. Thus, the first substrate 10 has a wiring pattern and serves as a lead frame.

The power element 30 is mounted on the first surface 11 of the first substrate 10 and electrically, mechanically connected to the first substrate 10 through a conductive material 80. Examples of the conductive material 80 can include a solder material such as eutectic solder or lead-free solder and a conductive adhesive containing filler metal, metal powder, nano metal particle, or the like.

The power element 30 can have a rectangular plate shape and be fabricated by applying a common semiconductor process to a semiconductor chip such as a silicon semiconductor chip. Examples of the power element 30 can include a power metal-oxide semiconductor (MOS) transistor, an insulated gate bipolar transistor (IGBT), and a power bipolar transistor.

The power element 30 generates a relatively large amount of heat when driven. The heat generated by the power element 30 is released through the first substrate 10. Therefore, it is preferable that the first substrate 10 be made of a material having good heat conductivity. For example, it is preferable that the first substrate 10 be made of a material that mainly contains copper, aluminum, or the like.

In an example shown in FIG. 1, the power element 30 is a power MOS transistor. The power element 30 includes a source electrode 32, a gate electrode 33, and a drain electrode 34. The power element 30 has a front surface 31 and a back surface opposite to the front surface 31. The front surface 31 faces the first surface 21 of the second substrate 20. The source electrode 32 and the gate electrode 33 are formed on the front surface 31. The drain electrode 34 is formed on the back surface.

For example, each of the source electrode 32 and the gate electrode 33 can be made of aluminum and have a rectangular planar shape on the front surface 31. For example, the drain electrode 34 can be made of titanium (Ti) or nickel (Ni) and formed on almost the entire back surface of the power element 30.

According to the first embodiment, a planar size of the gate electrode 33 is smaller than a planar size of the source electrode 32. For example, the gate electrode 33 can be about 0.1 mm to about 0.5 mm on a side.

The gate electrode 33 is electrically connected to the second substrate 20 through the second conductive member 60 and receives a control signal from the second substrate 20. The second substrate 20 includes a control circuit that is configured to control the power element 30 by outputting the control signal to the gate electrode 33.

A large amount of electric current flows between the source electrode 32 and the drain electrode 34. The source electrode 32 and the drain electrode 34 are electrically connected to the first substrate 10 through the first conductive member 50 and the conductive material 80, respectively. Details of the first conductive member 50 and the second conductive member 60 are described later.

As described previously, the second substrate 20 is stacked on the first substrate 10 in such a manner that the first surface 21 of the second substrate 20 faces the first surface 11 of the first substrate 10. The electronic component 40 is mounted on the first surface 21 of the second substrate 20. According to the first embodiment, another electronic component 40 is mounted on the second surface 22 of the second substrate 20.

The electronic component 40 mounted on the second substrate 20 is a different type from the power element 30 mounted on the first surface 11 of the first substrate 10. Examples of the electronic component 40 can include a large-scale integration (LSI) chip and a passive element such as a capacitor, a diode, or a resistor. The electronic component 40 is electrically connected to the second substrate 20 through a solder, an electrically conductive adhesive, a bonding wire, or the like.

According to the first embodiment, the first surfaces 11, 21 of the first and second substrates 10, 20 are spaced from each other by a predetermined distance to form accommodation space in which the power element 30 and the electronic component 40 are located.

The distance between the first surfaces 11, 21 of the first and second substrates 10, 20 prevents the power element 30 on the first surface 11 from being in contact with the first surface 21 and also prevents the electronic component 40 on the first surface 21 from being in contact with the first surface 11. For example, according to the embodiment, the distance can be set so that the front surface 31 of the power element 30 can be spaced from the first surface 21 of the second substrate 20 by one millimeter (1 mm) or more.

As shown in FIG. 1, the first substrate 10 has a spacer 13 that keeps the distance between the first surfaces 11, 21 of the first and second substrates 10, 20. For example, the spacer 13 can be formed by partially bending the first substrate 10 in a stacked direction (i.e., vertical direction in FIG. 1) in which the first and second substrates 10, 20 are stacked.

According to the first embodiment, an end portion of the first substrate 10 is bent to form the spacer 13. The spacer 13 extends in the stacked direction and has a length almost equal to the distance between the first surfaces 11, 21 of the first and second substrates 10, 20. In this way, the spacer 13 keeps the distance between the first surfaces 11, 21 of the first and second substrates 10, 20.

As shown in FIG. 1, according to the first embodiment, the spacer 13 is electrically connected to an end portion of the first surface 21 of the second substrate 20 through the conductive material 80. Thus, the first substrate 10 and the second substrate 20 are electrically connected together.

As described above, according to the first embodiment, the first substrate 10 is a lead frame. Therefore, the spacer 13 can be easily formed by bending the first substrate 10. Instead of the first substrate 10, the second substrate 20 can have the spacer 13. That is, the spacer 13 can be a single piece of the first substrate 10 or the second substrate 20. Alternatively, the first and second substrates 10, 20 can be spaced by a spacer that is a separate piece of the first and second substrates 10, 20.

According to the first embodiment, the first substrate 10 has an external input/output terminal 14 through which the electronic device S1 can be electrically connected to an external device (not shown). The external input/output terminal 14 is exposed outside the molding resin 70.

For example, the spacer 13 is bent and elongated in a direction perpendicular to the stacked direction so as to project from the molding resin 70. The projecting portion of the spacer 13 serves as the external input/output terminal 14.

As shown in FIG. 1, the second surface 12 of the first substrate 10 is exposed outside the molding resin 70. Thus, the heat generated by the power element 30 is efficiently released outside the molding resin 70 through the second surface 12 of the first substrate 10.

As described previously, the first conductive member 50 for electrically connecting the power element 30 to the first substrate 10 is electrically connected to the front surface 31 of the power element 30. Likewise, the second conductive member 60 for electrically connecting the power element 30 to the second substrate 20 is electrically connected to the front surface 31 of the power element 30.

It is noted that both the first and second conductive members 50, 60 are located between the first surfaces 11, 21 of the first and second substrates 10, 20 and cannot be seen when viewed from the stacked direction (i.e., vertical direction in FIG. 1). In other words, each of the first and second conductive members 50, 60 does not extend out of the first and second substrates 10, 20 when viewed from the stacked direction.

A first end of the first conductive member 50 is connected to the source electrode 32 on the front surface 31 of the power element 30, and a second end of the first conductive member 50 is connected to the first surface 11 of the first substrate 10. A middle portion between the first and second ends of the first conductive member 50 projects toward the second substrate 20 rather than the front surface 31 of the power element 30.

According to the first embodiment, the first conductive member 50 has a loop shape (i.e., curved shape with a rounded corner) projecting in an upward direction in FIG. 1. Alternatively, the first conductive member 50 can have a curved shape with a sharp corner projecting in the upward direction in FIG. 1. Examples of the first conductive member 50 can include a bonding wire and a ribbon wire made of copper, aluminum, or the like.

As described previously, the first surfaces 11, 21 of the first and second substrates 10, 20 are spaced from each other by the distance that prevents the power element 30 on the first surface 11 from being in contact with the first surface 21 and also prevents the electronic component 40 on the first surface 21 from being in contact with the first surface 11. Further, the distance prevents the first conductive member 50 from being in contact with the first surface 21 of the second substrate 20. Thus, although the first conductive member 50 projects toward the first surface 21 of the second substrate 20, the first conductive member 50 is spaced from the first surface 21 of the second substrate 20.

A first end of the second conductive member 60 is connected to the gate electrode 33 on the front surface 31 of the power element 30, and a second end of the second conductive member 60 is connected to the first surface 21 of the second substrate 20. Specifically, the second conductive member 60 extends above a top 51 of the first conductive member 50 in the stacked direction so that the second end of the second conductive member 60 can be connected to the first surface 21 of the second substrate 20.

It is noted that the shortest distance between the first conductive member 50 and the first surface 21 of the second substrate 20 in the stacked direction is between the top 51 and the first surface 21. That is, the first conductive member 50 is located closest to the first surface 21 at the top 51. A distance between the first and second ends of the second conductive member 60 is greater than a distance between the top 51 of the first conductive member 50 and the front surface 31 in the stacked direction.

As shown in FIG. 1, a longitudinal direction of the second conductive member 60 is parallel to the stacked direction. The second conductive member 60 stands on the front surface 31 in such a manner that the longitudinal direction of the second conductive member 60 is perpendicular to the front surface 31.

In other words, a height of the second end of the second conductive member 60 from the front surface 31 is greater than a height of the top 51 of the first conductive member 50 from the front surface 31. In summary, the length of the second conductive member 60 is greater than the height of the top 51 of the first conductive member 50 from the front surface 31.

According to the first embodiment, the second conductive member 60 is a metal lead having a columnar shape. Examples of the columnar shape can include a cylindrical rod shape, a rectangular rod shape, a thin strip shape, a thin ribbon shape, and a thin foil shape.

For example, the second conductive member 60 can be made of a metal material that mainly contains copper (Cu), aluminum (Al), gold (Au), or the like. Alternatively, the second conductive member 60 can be plated with such a metal material.

In particular, when the second conductive member 60 is connected to the second substrate 20 and the power element 30 through a solder, the second conductive member 60 can be plated with tin (Sn), nickel (Ni), gold (Au), or the like. In such an approach, reliability of electrical connection of the second conductive member 60 to the second substrate 20 and the power element 30 can be improved.

Like the first conductive member 50, the second conductive member 60 is provided to each power element 30. That is, when the electronic device S1 includes multiple power elements 30, the electronic device S1 includes multiple second conductive members 60.

As described previously, the first end of the second conductive member 60 is connected to the gate electrode 33 on the front surface 31, and the second end of the second conductive member 60 is connected to the second substrate 20. Specifically, the second end of the second conductive member 60 is connected to an electrode (not shown) on the first surface 21 of the second substrate 20.

In an example shown in FIG. 1, the second end of the second conductive member 60 is connected though the conductive material 80 to the first surface 21 of the second substrate 20. The conductive material 80 can be a solder, a conductive adhesive, or the like. Although not shown in the drawings, the first end of the second conductive member 60 is connected though the conductive material 80 to the front surface 31 of the power element 30.

As described above, the second conductive member 60 is connected through the conductive material 80 to each of the power element 30 and the second substrate 20. Alternatively, the second conductive member 60 can be connected directly to at least one of the power element 30 and the second substrate 20 by a metal bonding technique such as ultrasonic bonding or thermocompression bonding. For example, while the second end of the second conductive member 60 can be connected though the conductive material 80 to the first surface 21 of the second substrate 20, the first end of the second conductive member 60 can be connected directly to the front surface 31 of the power element 30 by such a metal bonding technique.

In this way, the source electrode 32 of the power element 30 is electrically connected to the first substrate 10 through the first conductive member 50, and the gate electrode 33 of the power element 30 is electrically connected to the second substrate 20 through the second conductive member 60.

As described previously, the planar size of the gate electrode 33 is smaller than the planar size of the source electrode 32.

For example, the gate electrode 33 can have a rectangular planar shape that is about 0.1 mm to about 0.5 mm on a side, and the front surface 31 of the power element 30 can be spaced from the first surface 21 of the second substrate 20 by one millimeter (1 mm) or more. According to this example, a ratio (i.e., aspect ratio) between length and width of the second conductive member 60 can be two or more. Despite small planar size of the gate electrode 33, the gate electrode 33 can be suitably connected to the second substrate 20 by using the second conductive member 60 having such aspect ratio.

In summary, according to the first embodiment, the power element 30 is located between the first and second surfaces 11, 21 of the first and second substrates 10, 20 and connected to the first substrate 10 through the first conductive member 50 that projects toward the second substrate 20.

Further, the power element 30 is connected to the second substrate 20 through the second conductive member 60. The height of the second conductive member 60 from the front surface 31 of the power element 30 is greater than the height of the top 51 of the first conductive member 50 from the front surface 31. The electronic component 40 is mounted on the second substrate 20 not to be in contact with the first substrate 10.

The first and second surfaces 11, 21 of the first and second substrates 10, 20 are spaced from each other by the distance that prevents the first conductive member 50 from being in contact with the first surface 21 of the second substrate 20.

The second conductive member 60 is located between the first and second surfaces 11, 21 of the first and second substrates 10, 20 and extends straightly from the power element 30 to the second substrate 20. Therefore, a planer side of the electronic device S1 can be reduced compared to a planar size of a conventional electronic device.

Thus, according to the first embodiment, although the power element 30 and the electronic component 40 are mounted between the first and second substrates 10, 20, the electronic device S1 can have a reduced size.

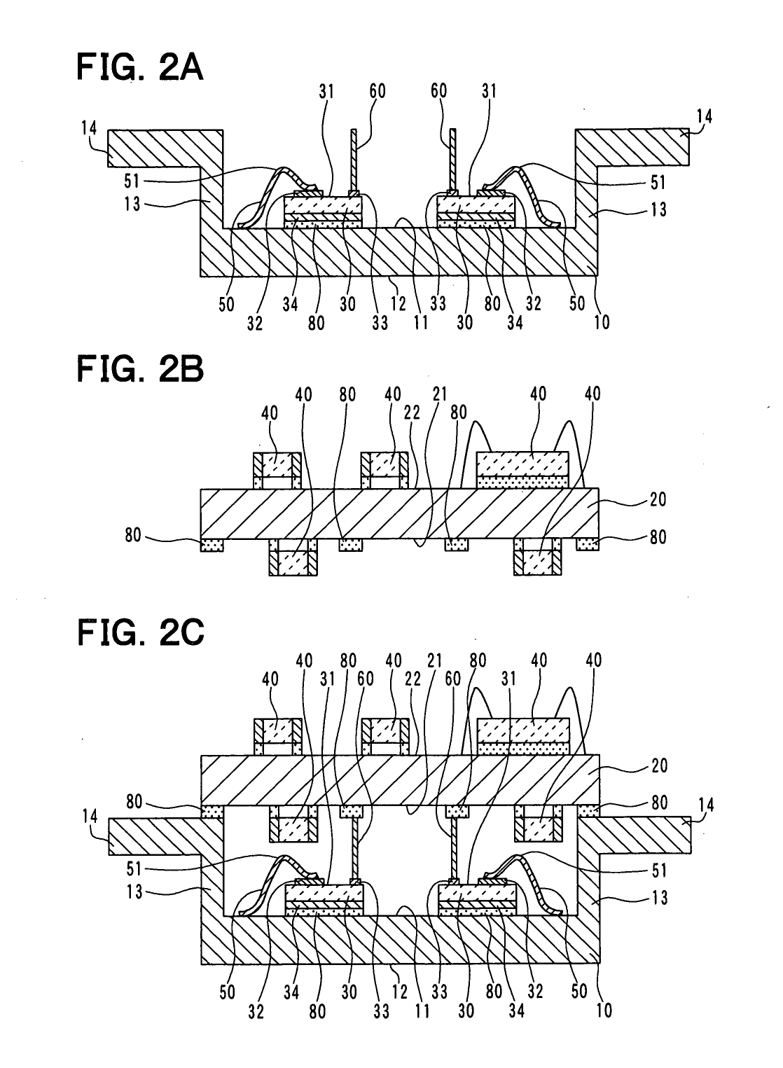

Next, a method of manufacturing the electronic device S1 is described below with reference to FIGS. 2A-2C.

In a process shown in FIG. 2A, the power element 30 is mounted on the first surface 11 of the first substrate 10. For example, the drain electrode 34 of the power element 30 is joined to the first surface 11 of the first substrate 10 through the conductive material 80.

Further, in the process shown in FIG. 2A, the first end of the first conductive member 50 is electrically connected to the source electrode 32 on the front surface 31 of the power element 30, and the second end of the first conductive member 50 is connected to the first substrate 10. The first end of the second conductive member 60 is electrically connected to the gate electrode 33.

Specifically, the first conductive member 50 is connected to the front surface 31 and the first substrate 10 in such a manner that the middle portion of the first conductive member 50 projects toward the second substrate 20 rather than the front surface 31. For example, the connection of the first conductive member 50 to the front surface 31 and the first substrate 10 can be achieved by a typical bonding method such as wire bonding or ribbon bonding.

Further, in the process shown in FIG. 2A, the first end of the second conductive member 60 is connected to the front surface 31 in such a manner that the second end of the second conductive member 60 can be located above the tip 51 of the first conductive member 50.

For example, the connection of the second conductive member 60 to the front surface 31 can be achieved by causing the second conductive member 60 to stand on the front surface 31 along its longitudinal direction through the conductive material 80 and then soldering the first end of the second conductive member 60 to the front surface 31 while keeping the second conductive member 60 standing on the front surface 31. Alternatively, the second conductive member 60 can be connected directly to the front surface 31 without using the conductive material 80 by performing ultrasonic bonding, thermocompression bonding, or the like, while keeping the second conductive member 60 standing on the front surface 31.

In a process shown in FIG. 2B, the electronic component 40 is mounted on the first surface 21 of the second substrate 20. For example, the electronic component 40 can mounted on the first surface 21 of the second substrate 20 through the conductive material 80, a bonding wire, or the like. According to the first embodiment, another electronic component 40 is mounted on the second surface 22 of the second substrate 20 in the same manner as the electronic component 40 on the first surface 21.

Further, in the process shown in FIG. 2B, the conductive material 80 is placed on the first surface 21 at positions where the second conductive member 60 and the spacer 13 of the first substrate 10 are to be connected.

Next, in a process shown in FIG. 2C, the first and second substrates 10, 20 are positioned with respect to each other so that the first surfaces 11, 21 of the first and second substrates 10, 20 can face each other and be spaced from each other by the distance that prevents the power element 30 on the first surface 11 from being in contact with the first surface 21, prevents the electronic component 40 on the first surface 21 from being in contact with the first surface 11, and also prevents the first conductive member 50 from being in contact with the first surface 21 of the second substrate 20.

At this time, the second end of the second conductive member 60 is placed in contact with the first surface 21 of the second substrate 20 through the conductive material 80. Likewise, the spacer 13 of the first substrate 10 is placed in contact with the first surface 21 of the second substrate 20 through the conductive material 80. When the conductive material 80 is a solder, reflow and cooling processes are performed while keeping the second conductive member 60 and the spacer 13 in contact with the first surface 21 through the conductive material 80. As a result, the second conductive member 60 and the second substrate 20 are joined together, and the first and second substrates 10, 20 are joined together. Alternatively, the second conductive member 60 can be joined directly to the second substrate 20 without using the conductive material 80 by performing ultrasonic bonding, thermocompression bonding, or the like.

Then, the first and second substrates 10, 20 that are joined together are placed in a mold, and a typical molding martial such as epoxy resin is injected into the mold. In this way, the first and second substrates 10, 20, the power element 30, the electronic component 40, and the first and second conductive members 50, 60 are encapsulated in the molding resin 70 by a transfer molding method.

Then, if necessary, an unnecessary portion of the first substrate 10 is cut off. Thus, the electronic device S1 shown in FIG. 1 can be manufactured.

### Second Embodiment

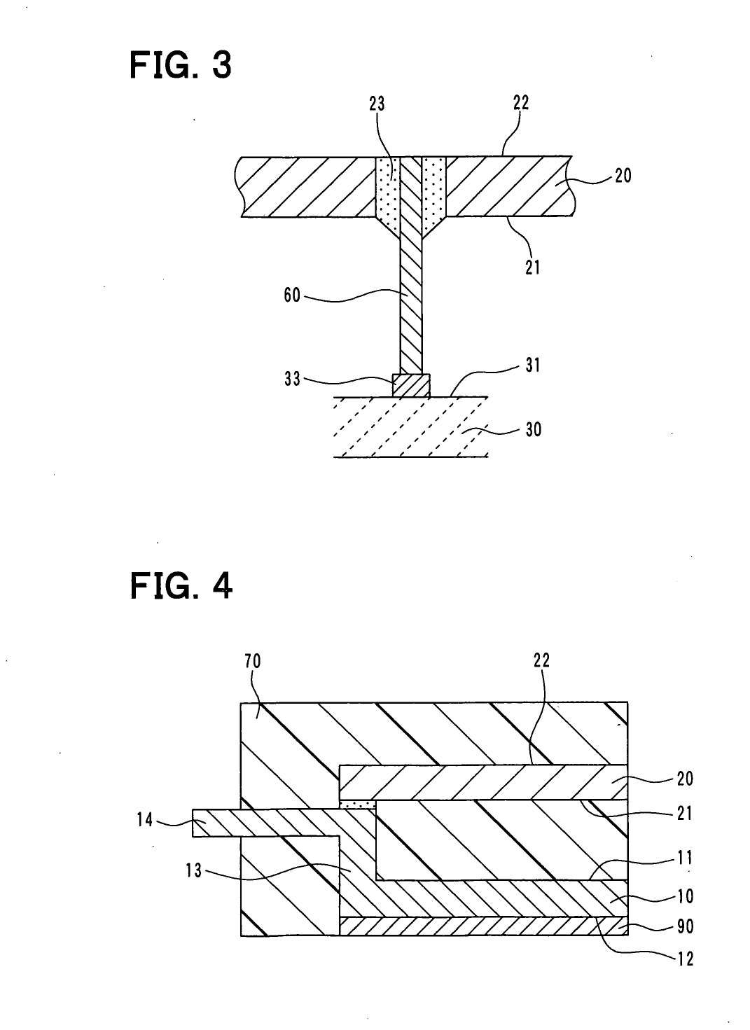

A second embodiment of the present invention is described below with reference to FIG. 3. A difference of the second embodiment from the first embodiment is as follows.

In the first embodiment, the second end of the second conductive member 60 is connected to the first surface 21 of the second substrate 20. Specifically, the second end of the second conductive member 60 is connected to the electrode (not shown) on the first surface 21 indirectly through the conductive material 80 or directly without the conductive material 80.

In contrast, in the second embodiment, as shown in FIG. 3, the second end of the second conductive member 60 is inserted in a hole 23 of the second substrate 20 and electrically connected to the second substrate 20 through a solder or the like inside the hole 23. The hole 23 extends from the first surface 21 toward the second surface 22.

In FIG. 3, the hole 23 is a through hole that penetrates the second substrate 20. Alternatively, the hole 23 can be a blind hole that has a bottom inside the second substrate 20.

### Third Embodiment

A third embodiment of the present invention is described below with reference to FIG. 4. A difference of the third embodiment from the first embodiment is as follows.

In the first embodiment, as shown in FIG. 1, the second surface 12 of the first substrate 10 is exposed outside the molding resin 70 so that the heat generated by the power element 30 can be efficiently released outside the molding resin 70 through the exposed second surface 12.

In contrast, in the third embodiment, as shown in FIG. 4, a heat radiator 90 such as a heatsink is mounted on the second surface 12 of the first substrate 10 so that the second surface 12 of the first substrate 10 can be covered with the heat radiator 90. The heat radiator 90 is exposed outside the molding resin 70 so that the heat generated by the power element 30 can be efficiently released outside the molding resin 70 through the exposed heat radiator 90.

Alternatively, the second surface 12 of the first substrate 10 can be encapsulated with the molding resin 70 without using the heat radiator 90. Even in such a case, the heat generated by the power element 30 can be released outside the molding resin 70 through the molding resin 70.

The structures of the second and third embodiments can be combined.

### Fourth Embodiment

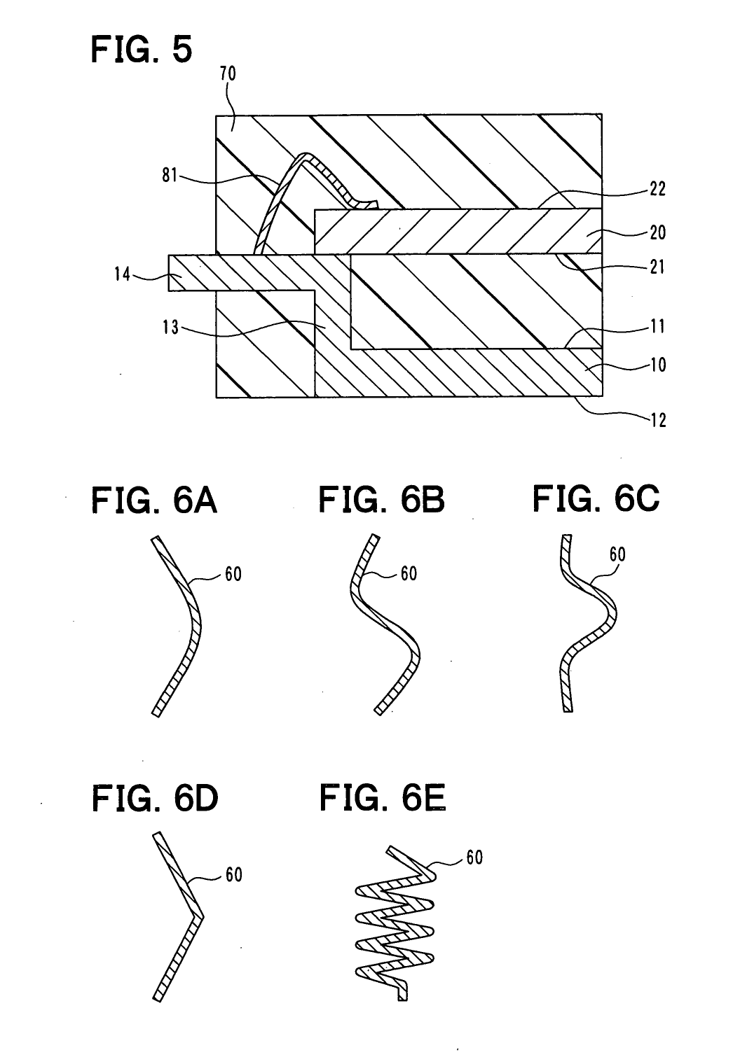

A fourth embodiment of the present invention is described below with reference to FIG. 5. A difference of the fourth embodiment from the first embodiment is as follows.

In the first embodiment, the spacer 13 of the first substrate 10 is electrically connected through the conductive material 80 to the end portion of the first surface 21 of the second substrate 20 so that the first and second substrates 10, 20 can be electrically connected together.

In contrast, in the fourth embodiment, as shown in FIG. 5, the first and second substrates 10, 20 are electrically connected together through a metal wire 81 such as a ribbon wire. In this case, the first and second substrates 10, 20 can be in direct contact with each other without the conductive material 80.

The structures of the second, third, and fourth embodiments can be combined.

### Fifth Embodiment

A fifth embodiment of the present invention is described below with reference to FIGS. 6A-6E. A difference of the fifth embodiment from the first embodiment is as follows.

In the first embodiment, the second conductive member 60 has a straight shape extending along its longitudinal direction.

In contrast, in the fifth embodiment, the second conductive member 60 has a shape other than a straight shape. Specifically, the second conductive member 60 is curved or bent in a direction crossing its longitudinal direction. For example, as shown in FIG. 6A, the second conductive member 60 can have a curved shape with one rounded top. Alternatively, as shown in FIG. 6B, the second conductive member 60 can have a curved shape with multiple rounded tops. Alternatively, as shown in FIG. 6C, the second conductive member 60 can have a shape with one rounded top between straight portions. Alternatively, as shown in FIG. 6D, the second conductive member 60 can have a bent shape with one sharp top. Alternatively, as shown in FIG. 6E, the second conductive member 60 can have a spring shape. It is noted that the shape of the second conductive member 60 is not limited to the shapes shown in FIGS. 6A-6E.

As described above, according to the fifth embodiment, the second conductive member 60 has a curved or bent shape. In such an approach, stress applied by the first and second substrates 10, 20 to the second conductive member 60 can be absorbed. Further, even when the first surfaces 11, 21 of the first and second substrates 10, 20 have unevenness, the second conductive member 60 can absorb the unevenness. Therefore, the first and second substrates 10, 20 can be accurately positioned with respect to each other so that the electronic device S1 can be accurately manufactured.

The second conductive member 60 can be easily formed in such curved or bent shapes by a common bending technique. The structures of the second, third, fourth, and fifth embodiments can be combined.

### Sixth Embodiment

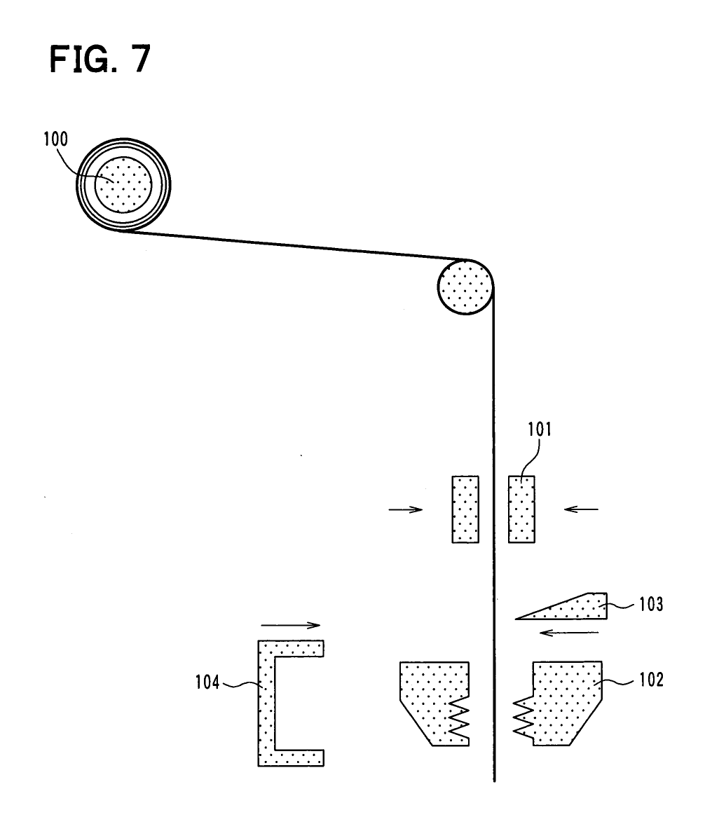

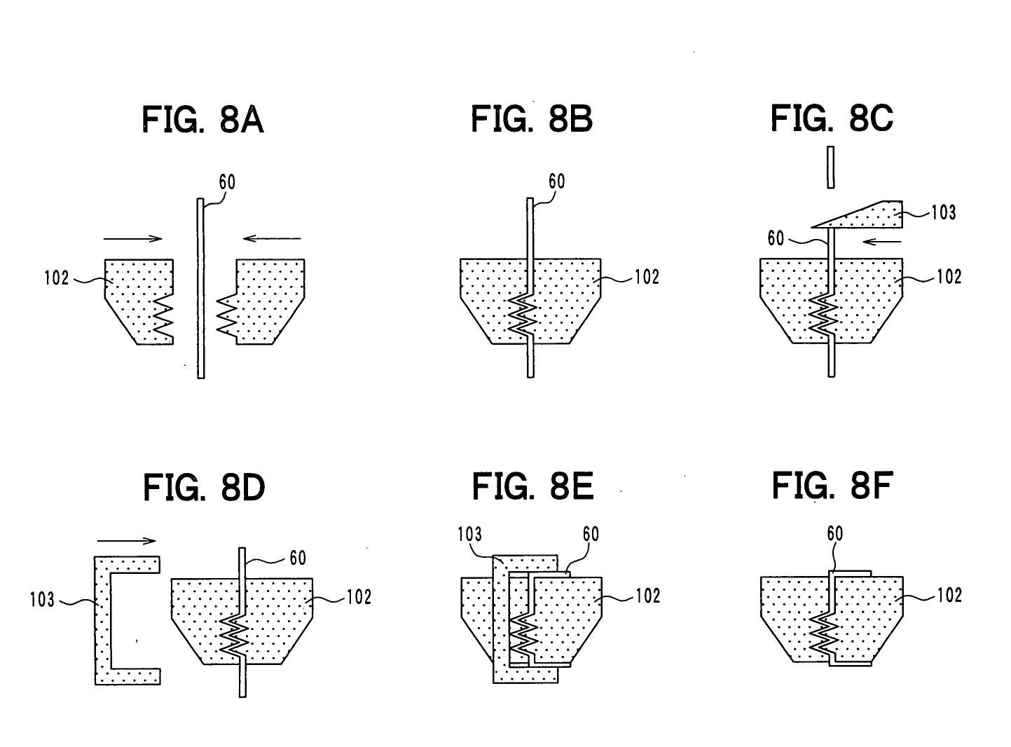

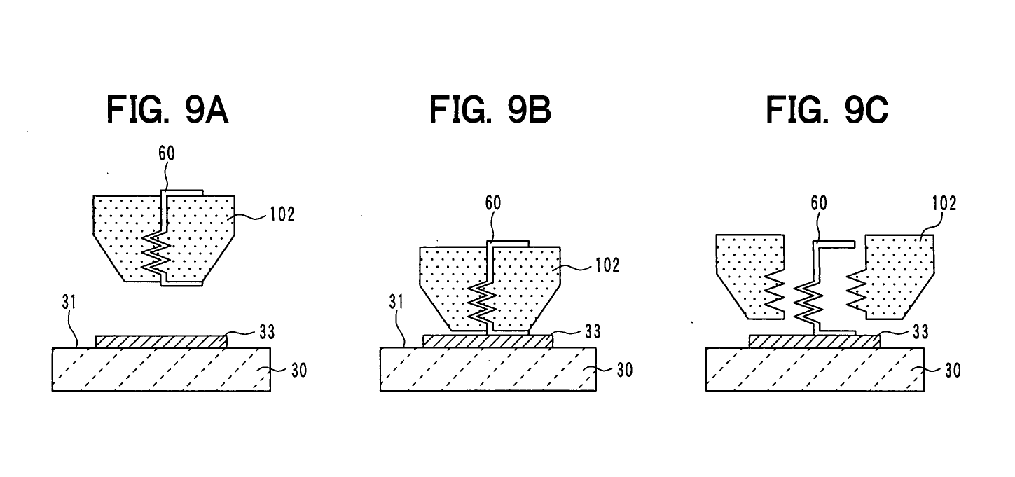

A sixth embodiment of the present invention is described below with reference to FIG. 7, FIGS. 8A-8F, and FIGS. 9A-9C. The sixth embodiment relates to another method of manufacturing the electronic device S1. FIG. 7 shows a machine used in the method according to the sixth embodiment. As shown in FIG. 7, the machine includes a reel 100, a clamper 101, a jig 102, a cutter 103, and a slider 104.

For example, the second conductive member 60 is metal foil of copper or the like and wound onto the reel 100.

The second conductive member 60 is pulled from the reel 100, passed through the clamper 101, and then supplied to the jig 102. The clamper 101 is a fastening tool to secure the second conductive member 60 by holding the second conductive member 60.

The jig 102 has a pair of uneven surfaces that face each other and are engageable with each other. The second conductive member 60 is passed between the facing surfaces of the jig 102. The jig 102 is operated so that the facing surfaces can move in different directions (i.e., lateral direction in FIG. 7) perpendicular to the facing surfaces. Thus, the facing surfaces of the jig 102 can be engaged and unengaged. Further, the jig 102 is operated so that the facing surfaces can move in the same direction (i.e., vertical direction in FIG. 7) parallel to the facing surfaces. For example, the jig 102 can be operated by an electric actuator.

The cutter 103 is used to cut off the second conductive member 60. The slider 104 is used to bend the second conductive member 60 outside the jig 102. Each of the clamper 101, the cutter 103, and the slider 104 can move in a direction indicated by a corresponding arrow in FIG. 7.

The second conductive member 60 is formed in a predetermined shape and connected to the front surface 31 of the power element 30 by using the machine shown in FIG. 7. FIGS. 8A-8F show a method of forming the second conductive member 60 in the predetermined shape. FIGS. 9A-9C show a method of connecting the second conductive member 60 to the front surface 31.

In a process shown in FIG. 8A, the second conductive member 60 is passed between the facing surfaces of the jig 102 in such a manner that a middle portion of the second conductive member 60 can be located between the facing surfaces of the jig 102. In other words, the second conductive member 60 is passed between the facing surfaces of the jig 102 in such a manner that a first end of the second conductive member 60 can be located outside the jig 102.

Then, in a process shown in FIG. 8B, the jig 102 is operated so that the facing surfaces of the jig 102 can be engaged with each other. As a result, the second conductive member 60 is sandwiched between the facing surfaces of the jig 102 and pressed into a shape depending on the unevenness of the facing surfaces of the jig 102. In this way, the second conductive member 60 has a shape that is curved or bent in the direction crossing its longitudinal direction. Then, in a process shown in FIG. 8C, the second conductive member 60 is cut off by the cutter 103 so that a second end of the second conductive member 60 can be formed.

Then, in a process shown in FIG. 8D, the slider 104 is operated so as to move toward the jig 102 in the direction perpendicular to the longitudinal direction of the second conductive member 60. Thus, as shown in FIG. 8E, the slider 104 is fitted on the jig 102 so that the first and second ends of the second conductive member 60 can be bent in the same direction perpendicular to the longitudinal direction of the second conductive member 60. In this way, the second conductive member 60 is formed in the predetermined shape as shown in FIG. 8F.

Then, in a process shown in FIG. 9A, the jig 102 is positioned with respect to the power element 30 in such a manner that the first end of the second conductive member 60 held by the jig 102 faces the front surface 31 of the power element 30. Then, in a process shown in FIG. 9B, the jig 102 is operated so that the first end of the second conductive member 60 can be in contact with the gate electrode 33 on the front surface 31. Then, the jig 102 and/or the power element 30 are heated so that the first end of the second conductive member 60 can be joined to the gate electrode 33. That is, the first end of the second conductive member 60 is joined to the gate electrode 33 by a thermocompression bonding method.

Then, in a process shown in FIG. 9C, the jig 102 is operated so that the facing surfaces of the jig 102 can be unengaged. Thus, the second conductive member 60 is detached from the jig 102.

In this way, the second conductive member 60 is formed in the predetermined shape and then joined to the front surface 31 in such a manner that the second conductive member 60 stands on the front surface 31.

According to the sixth embodiment, the second conductive member 60 is joined to the power element 30 by a thermocompression bonding method. Alternatively, the second conductive member 60 can be joined to the power element 30 through the conductive material 80.

According to the sixth embodiment, the first and second ends of the second conductive member 60 are bent by the slider 104 in the direction perpendicular to its longitudinal direction. In such an approach, the first end of the second conductive member 60 becomes parallel to the front surface 31 of the power element 30, and the second end of the second conductive member 60 becomes parallel to the first surface 21 of the second substrate 20. Therefore, the second conductive member 60 can be easily joined to the power element 30 and the second substrate 20. Alternatively, the process of bending the first and second ends of the second conductive member 60 by the slider 104 can be omitted.

### Seventh Embodiment

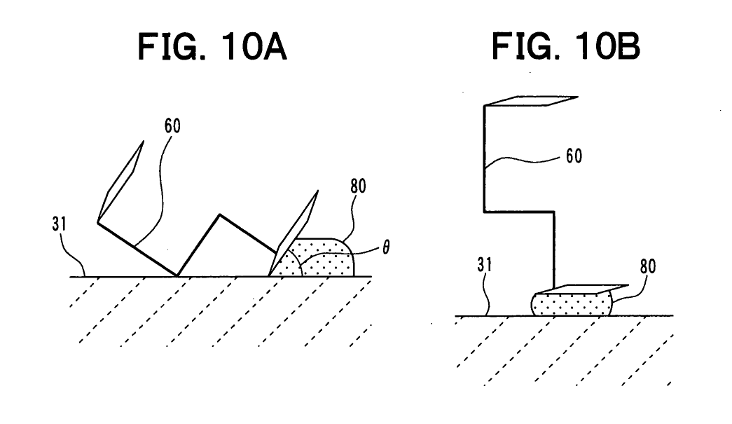

A seventh embodiment of the present invention is described below with reference to FIGS. 10A and 10B. The seventh embodiment relates to another method of manufacturing the electronic device S1. According to the seventh embodiment, the second conductive member 60 is joined through the conductive material 80 to the front surface 31 of the power element 30 while keeping the second conductive member 60 standing on the front surface 31. It is noted that the conductive material 80 is a solder.

FIG. 10A shows a condition where the second conductive member 60 in contact with the second conductive member 60 lies on the front surface 31 of the power element 30. FIG. 10B shows a condition where the second conductive member 60 in contact with the second conductive member 60 stands on the front surface 31 of the power element 30 due to surface tension of the conductive material 80.

In a process shown in FIG. 10A, the first end of the second conductive member 60 is placed in contact with the conductive material 80 on the front surface 31 of the power element 30 while keeping the second conductive member 60 lying on the front surface 31.

Then, in a process shown in FIG. 10B, the conductive material 80 is melted by a reflow process so that the second conductive member 60 can stand on the front surface 31 due to surface tension of the melted conductive material 80. In the field of soldering, this effect is known as “Manhattan effect”. Then, a cooling process is performed while keeping the second conductive member 60 standing on the front surface 31.

Thus, the second conductive member 60 is joined to the power element 30 in such a manner that the first end of the second conductive member 60 can be parallel to the front surface 31 of the power element 30 through the conductive material 80.

In the process shown in FIG. 10A, it is preferable that the second conductive member 60 lie on the front surface 31 in such a manner that an angle θ formed by the first end of the second conductive member 60 and the front surface 31 can be 45° or less. The present inventors have conducted an experiment and found that the second conductive member 60 can almost surely (i.e., almost 100%) stand on the front surface 31 due to the surface tension when the angle θ is 45° or less. The result of the experiment shows that the second conductive member 60 sometimes fails to stand on the front surface 31 when the angle θ is 60°.

In an example shown in FIGS. 10A and 10B, the first end of the second conductive member 60 is bent in a L-shape so that a contact area between the first end of the second conductive member 60 and the conductive material 80 can be increased. In such an approach, it is likely that the second conductive member 60 will stand due to the surface tension of the conductive material 80.

### Modifications

The embodiments described above can be modified in various ways, for example, as follows.

In the embodiments, the electronic component 40 is mounted on each of the first surface 21 and the second surface 22 of the second substrate 20. Alternatively, the electronic component 40 can be mounted on only the first surface 21 of the second substrate 20.

In the embodiments, the first and second substrates 10, 20, the power element 30, the electronic component 40, and the first and second conductive members 50, 60 are encapsulated with the molding resin 70. Alternatively, the molding resin 70 can be omitted.

In the embodiments, the first substrate 10 is a lead frame, and the second substrate 20 is a circuit board. Alternatively, the first substrate 10 and the second substrate 20 can be other types of substrates, on which the power element 30 and the electronic component 40 can be mounted.

In the embodiments, the first conductive member 50 is connected to the source electrode 32 of the power element 30, and the second conductive member 60 is connected to the gate electrode 33 of the power element 30. Alternatively, the first and second conductive members 50, 60′ can be connected to other electrodes of the power element 30.

Such changes and modifications are to be understood as being within the scope of the present invention as defined by the appended claims.

What is claimed is:

1. An electronic device comprising:
a first substrate having a surface;
a second substrate having a surface located facing the surface of the first substrate;
a power element mounted on the surface of the first substrate and having a surface facing the surface of the second substrate;
an electronic component mounted on the surface of the second substrate;
a first conductive member configured to electrically connect the power element to the first substrate, the first conductive member having a first end connected to the surface of the power element, a second end connected to the surface of the first substrate, and a middle portion between the first and second, the middle portion projecting toward the second substrate so that a top of the middle portion is located closer to the surface of the second substrate than the surface of the power element; and
a second conductive member configured to electrically connect the power element to the second substrate, the second conductive member having a first end connected to the surface of the power element and a second end extending above the top of the middle portion of the first conductive member and connected to the surface of the second substrate, wherein
the surfaces of the first and second substrates are spaced from each other by a predetermined distance that prevents the power element from being in contact with the surface of the second substrate, prevents the electronic component from being in contact with the surface of the first substrate, and prevents the first conductive member from being in contact with the surface of the second substrate.

2. The electronic device according to claim 1, wherein
the power element includes a first electrode on the surface of the power element and a second electrode on the surface of the power element, the first electrode having a surface connected to the first end of the first conductive member, the second electrode having a surface connected to the first end of the second conductive member, and
a size of the surface of the second electrode is smaller than a size of the surface of the first electrode.

3. The electronic device according to claim 1, wherein
the second conductive member is a columnar lead of metal and stands on the surface of the power element in such a manner that a longitudinal direction of the second conductor member is perpendicular to the surface of the power element.

4. The electronic device according to claim 3, wherein
the second conductive member is bent in a direction crossing the longitudinal direction.

5. The electronic device according to claim 1, wherein
the second conductive member is made of a metal material that mainly contains copper, aluminum, or gold.

6. The electronic device according to claim 1, wherein
the first end of the second conductive member is connected to the power element through a solder or a conductive adhesive.

7. The electronic device according to claim 1, wherein
the second end of the second conductive member is connected to the second substrate through a solder or a conductive adhesive.

8. The electronic device according to claim 1, wherein
the second conductive member comprises a plurality of second conductive members.

9. The electronic device according to claim 1, further comprising:
a molding resin member, wherein
the first substrate, the second substrate, the power element, the electronic component, the first conductive member, and the second conductive member are covered and sealed with the molding resin member.

10. A method of manufacturing an electronic device comprising:
placing a back surface of a power element on a surface of a first substrate;
placing an electronic component on a surface of a second substrate;
connecting a first conductive member to each of the power element and the first substrate in such a manner that a first end of the first conductive member is connected to a front surface of the power element, a second end of the first conductive member is connected to the surface of the first substrate, and a middle portion between the first and second ends of the first conductive member projects in a direction away from the surface of the first substrate;
preparing a jig having a pair of facing surfaces that are engageable with each other;
preparing a second conductive member having a longitudinal direction, the second conductive member being a metal lead having a columnar shape;
holding a middle portion of the second conductive member in the longitudinal direction between the pair of facing surfaces of the jig so that the middle portion of the second conductive member is bent in a direction crossing the longitudinal direction;
connecting a first end of the second conductive member to the front surface of the power element while keeping the middle portion of the second conductive member held between the pair of facing surfaces of the jig in such a manner that the longitudinal direction of the second conductive member is perpendicular to the front surface of the power element and that a second end of the first conductive member is located above a tip of the middle portion of the first conductive member, and;
positioning the first and second substrates with respect to each other in such a manner the surfaces of the first and second substrates face each other with a predetermined distance that prevents the power element from being in contact with the surface of the second substrate, prevents the electronic component from being in contact with the surface of the first substrate, and prevents the first conductive member from being in contact with the surface of the second substrate, wherein
the positioning includes connecting the second end of the second conductive member to the surface of the second substrate.
